(19) United States
(12) Patent Application Publication
(10) Pub. No.: US 2024/0054262 A1
(43) Pub. Date: Feb. 15, 2024

(54) CARBON EMISSION FLOW CALCULATION METHOD AND APPARATUS FOR REGIONAL INTEGRATED ENERGY SYSTEM

(71) Applicant: TSINGHUA UNIVERSITY, Beijing (CN)

(72) Inventors: Ning ZHANG, Beijing (CN); Yanghao YU, Beijing (CN); Yaohua CHENG, Beijing (CN); Peng WANG, Beijing (CN); Zhaoyi WEI, Beijing (CN); Yaowang LI, Beijing (CN); Ershun DU, Beijing (CN); Chongqing KANG, Beijing (CN)

(21) Appl. No.: 18/490,744

(22) Filed: Oct. 19, 2023

Related U.S. Application Data
(63) Continuation of application No. PCT/CN2023/071313, filed on Jan. 9, 2023.

(30) Foreign Application Priority Data
Feb. 24, 2022 (CN) 202210172385.4

(51) Int. Cl. G06F 30/20

(52) U.S. Cl. CPC G06F 30/20

(57) ABSTRACT

Provided is a carbon emission flow calculation method for a regional integrated energy system. The method includes: establishing a single-period steady-state carbon emission flow model of an energy conversion device by modeling carbon emission of each single-input-single-output conversion device and each single-input-multi-output conversion device; obtaining a matrix expression of carbon emission flow based on the single-period steady-state carbon emission flow model of the energy conversion device and establishing a single-period steady-state carbon emission flow model of the regional integrated energy system; and establishing a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

### CROSS-REFERENCE TO RELATED APPLICATIONS

This application is a continuation of International Application No. PCT/CN2023/071313, filed on Jan. 9, 2023, which is based on and claims priority to Chinese Patent Application No. 202210172385.4, filed on Feb. 24, 2022, the entire content of which is incorporated herein by reference.

### FIELD

The present disclosure relates to the technical field of low-carbon energy systems, and more particularly, to a carbon emission flow calculation method and an apparatus for a regional integrated energy system.

### BACKGROUND

In main national economic production departments, an energy system is the largest carbon emission source, and low-carbon transformation and sustainable development of the energy system are very important for achieving carbon emission control target. In order to reduce carbon emission of energy and promote the efficient and clean utilization of the energy. integrated energy systems are proposed.

The integrated energy system, also called as a multi-energy system or an energy internet, is a comprehensive system formed by coupling various types of energy such as electric power, heat, natural gas, water energy, solar energy. wind energy, and the like. A regional integrated energy system, also called Energy Hub (EH), is the core of the integrated energy system for energy conversion and storage. The regional integrated energy system is a multi-energy integrated system in a small space, such as an industrial park, a town energy system, and the like, mainly realizes the conversion, distribution, and storage of the energy, has small scale of concerned energy networks, and mainly includes a low-voltage power distribution network, a gas distribution network, and a regional heat network.

In the context of climate change and sustainable development, analysis and calculation of carbon emissions are fundamental and critical efforts for integrated energy systems to achieve low carbon. A carbon emission calculation method of the energy system mainly includes a macroscopic statistical method, a full life cycle method, a carbon emission flow method, and the like. These methods are significantly different from each other in the fineness of calculation results, requirements on basic data and starting points, so that the application scenes in which these methods are applied are different from each other. However. both the macroscopic statistical method and the full life cycle method are disjointed from actual physical characteristics of the regional integrated energy system, so that space-time transfer mechanism of the carbon emission in the regional integrated energy system cannot be clarified. As a result, guidance for optimization decisions of the regional integrated energy system is limited, which is urgently needed to be improved.

### SUMMARY

The present disclosure is based on the inventor's recognition and discovery of the following problems.

Analysis and calculation of carbon emission are fundamental and critical efforts for realizing low carbonization of an integrated energy system, and a carbon emission flow method is to use a power flow tracking method for carbon flow tracking by utilizing analysis idea of a network flow and discloses basic characteristics and rules of virtual carbon emission flow in an energy network. In the related art, a carbon emission flow calculation method is proposed by establishing a carbon emission flow model combined with a power grid network structure and physical characteristics.

In summary, in the field of low-carbon energy systems, it is necessary to provide a carbon emission flow calculation method and an apparatus for a regional integrated energy system, which is based on modification and improvement on the existing carbon emission flow calculation method for a power system, and can accurately calculate carbon emission in energy conversion, distribution, storage and others in the regional integrated energy system, to provide a basic theory for low-carbon analysis and optimization decision of the integrated energy system.

The present disclosure provides a carbon emission flow calculation method and an apparatus for a regional integrated energy system, to solve problems that actual physical characteristics of the regional integrated energy system are disjointed from the methods in the related art, so that a space-time transfer mechanism of carbon emission in the regional integrated energy system cannot be clarified, and thus guidance on optimization decisions of the regional integrated energy system is limited and the like.

In a first aspect of embodiments of the present disclosure, a carbon emission flow calculation method for a regional integrated energy system is provided. The method includes: establishing a single-period steady-state carbon emission flow model of an energy conversion device by modeling carbon emission of each of a single-input-single-output conversion device and a single-input-multi-output conversion device; obtaining a matrix expression of carbon emission flow based on the single-period steady-state carbon emission flow model of the energy conversion device and establishing a single-period steady-state carbon emission flow model of the regional integrated energy system; and establishing a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

In some embodiments of the present disclosure, a first carbon flow density relationship between an input port and an output port of the single-input-single-output conversion device satisfies:

ρₒ^{I}=ρᵢ^{I}Vᵢ^{I}/Vₒ^{I}=ρᵢ^{I}/η^{I},

where ρᵢ^{I} represents a carbon flow density at the input port of the single-input-single-output conversion device, ρₒ^{I} represents a carbon flow density at the output port of the single-input-single-output conversion device, Vᵢ^{I} represents input energy flow, Vₒ^{I} represents output energy flow, and η^{I} represents an efficiency. A second carbon flow density relationship between an input port and output ports of the single-input-multi-output conversion device satisfies:

$${ρ}_{o , W}^{CHP} = \frac{{ρ}_{i}^{CHP}}{{η}^{W} + {ϵη}^{Q}} ,$$

$${ρ}_{o , Q}^{CHP} = \frac{{ϵρ}_{i}^{CHP}}{{η}^{W} + {ϵη}^{Q}} ,$$

where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and e represents a ratio of exergy to energy of a working medium.

In some embodiments of the present disclosure, the obtaining the matrix expression of the carbon emission flow based on the single-period steady-state carbon emission flow model of the energy conversion device and establishing the single-period steady-state carbon emission flow model of the regional integrated energy system includes: determining a first carbon emission coupling matrix and a second carbon emission coupling matrix of the regional integrated energy system based on the first carbon flow density relationship and the second carbon flow density relationship, respectively; and calculating carbon flow rates at all output ports based on the first carbon emission coupling matrix and the second carbon emission coupling matrix.

In some embodiments of the present disclosure, the calculating the carbon flow rates at all the output ports based on the first carbon emission coupling matrix and the second carbon emission coupling matrix includes: obtaining carbon flow density vectors at the output ports based on the first carbon emission coupling matrix and the second carbon emission coupling matrix; and obtaining the carbon flow rates at all the output ports based on the carbon flow density vectors at the output ports. The carbon flow rates are each calculated based on the following equation:

Rₒ=ρₒ∘Vₒ,

where ρₒ represents the carbon flow density vector at each of the output ports. Vₒ represents an output energy column vector, and ∘ represents a corresponding multiplication (Hadamard product) of two vector elements.

In some embodiments of the present disclosure, the establishing the standardized multi-period carbon emission flow model of the regional integrated energy system by combining the multi-period coupled steady-state carbon emission flow model of the energy storage device and the single-period steady-state carbon emission flow model of the regional integrated energy system includes: determining internal stored energy based on a current operating state of the energy storage device, and obtaining corresponding carbon emission, to determine a stored carbon flow rate; and establishing a period coupling relationship of the stored carbon flow rate based on the stored carbon flow rate, and determining a carbon flow density at an energy storage input port and a carbon flow density at an energy storage output port in any period, to generate the standardized multi-period carbon emission flow model.

In a second aspect according to embodiments of the present disclosure, a carbon emission flow calculation apparatus for a regional integrated energy system is provided. The carbon emission flow calculation apparatus includes a first modeling unit, a second modeling unit, and a calculation unit. The first modeling unit is configured to establish a single-period steady-state carbon emission flow model of an energy conversion device by modeling carbon emission of each single-input-single-output conversion device and each single-input-multi-output conversion device. The second modeling unit is configured to obtain a matrix expression of carbon emission flow based on the single-period steady-state carbon emission flow model of the energy conversion devices and to establish a single-period steady-state carbon emission flow model of the regional integrated energy system. The calculation unit is configured to establish a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

In some embodiments of the present disclosure, a first carbon flow density relationship between an input port and an output port of the single-input-single-output conversion device satisfies:

$${ρ}_{o}^{I} = \frac{{ρ}_{i}^{I} {V}_{i}^{I}}{{V}_{o}^{I}} = \frac{{ρ}_{i}^{I}}{{η}^{I}} ,$$

where ρᵢ^{I} represents a carbon flow density at the input port of the single-input-single-output conversion device, ρ₀^{I} represents a carbon flow density at the output port of the single-input-single-output conversion device. Vᵢ^{I} represents input energy flow, Vₒ^{I} represents output energy flow, and η^{I} represents an efficiency; and a second carbon flow density relationship between an input port and output ports of the single-input-multi-output conversion device satisfies:

$${ρ}_{o , W}^{CHP} = \frac{{ρ}_{i}^{CHP}}{{η}^{W} + {ϵη}^{Q}} ,$$

$${ρ}_{o , Q}^{CHP} = \frac{{ϵρ}_{i}^{CHP}}{{η}^{W} + {ϵη}^{Q}} ,$$

where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and ϵ represents a ratio of exergy to energy of a working medium.

In some embodiments of the present disclosure, the second modeling unit includes a conversion sub-unit and a calculation sub-unit. The conversion sub-unit is configured to determine a first carbon emission coupling matrix and a second carbon emission coupling matrix of the regional integrated energy system based on the first carbon flow density relationship and the second carbon flow density relationship, respectively. The calculation sub-unit configured to calculate carbon flow rates at all output ports based on the first carbon emission coupling matrix and the second carbon emission coupling matrix.

In some embodiments of the present disclosure, the calculation sub-unit is further configured to: obtain carbon flow density vectors at the output ports based on the first carbon emission coupling matrix and the second carbon emission coupling matrix, and obtain the carbon flow rates at all the output ports based on the carbon flow density vectors at the output ports. The carbon flow rates are each calculated based on the following equation:

Rₒ=ρₒ∘Vₒ,

where ρₒ represents the carbon flow density vector at each of the output ports, Vₒ represents an output energy column vector, and ∘ represents a corresponding multiplication (Hadamard product) of two vector elements.

In some embodiments of the present disclosure, the calculation unit is further configured to: determine internal stored energy based on a current operating state of the energy storage device, and obtain corresponding carbon emission, to determine a stored carbon flow rate; and establish a period coupling relationship of the stored carbon flow rate based on the stored carbon flow rate, and determine a carbon flow density at an energy storage input port and a carbon flow density at an energy storage output port in any period, to generate the standardized multi-period carbon emission flow model.

In a third aspect according to embodiments of the present disclosure, an electronic device is provided. The electronic device includes a memory, a processor, and a computer program stored in the memory and executable on the processor. The processor is configured to execute the computer program to implement the carbon emission flow calculation method for the regional integrated energy system as described in the above embodiments.

In a fourth aspect according to embodiments of the present disclosure, a computer-readable storage medium is provided. The computer-readable storage medium has a computer program stored thereon. The computer program, when executed by a processor, implements the carbon emission flow calculation method for the regional integrated energy system as described in the above embodiments.

According to the embodiments of the present disclosure, the standardization modeling of the carbon emission of the regional integrated energy system can be obtained by establishing the steady-state carbon emission flow model of the regional integrated energy system based on the matrix expression of carbon emission flow, thereby obtaining the actual carbon emission flow of the regional integrated energy system. Therefore, it is possible to provide an accurate and effective method for analysis and measurement of the carbon emission of the regional integrated energy system, and basis for clarifying carbon emission responsibilities of different energy systems, measuring enussion reduction contributions of different subjects, and discovering and identifying low-carbon weak links in the system. As a result, problems that the actual physical characteristics of the regional integrated energy system are disjointed from the methods in the related art, so that the space-time transfer mechanism of carbon emission in the regional integrated energy system cannot be clarified, and thus the guidance on the optimization decisions of the regional integrated energy system is limited and the like, can be solved.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings, in which:

FIG. 1 is a flowchart of a carbon emission flow calculation method for a regional integrated energy system according to an embodiment of the present disclosure;

FIG. 2 is a simple energy hub diagram illustrating a carbon emission coupling matrix solution process according to an embodiment of the present disclosure;

FIG. 3 is a schematic diagram illustrating a principle of a carbon emission flow calculation method for a regional integrated energy system according to an embodiment of the present disclosure;

FIG. 4 is a schematic structural diagram of a carbon emission flow calculation apparatus for a regional integrated energy system according to an embodiment of the present disclosure; and

FIG. 5 is a schematic structural diagram of an electronic device according to an embodiment of the present disclosure.

### DETAILED DESCRIPTION

Embodiments of the present disclosure will be described in detail below, examples of these embodiments are illustrated in the accompanying drawings, throughout which same or similar elements, or elements having same or similar functions, are denoted by same or similar reference numerals. The embodiments described below with reference to the accompanying drawings are illustrative merely, and are intended to explain, rather than limiting, the present disclosure.

A carbon emission flow calculation method and an apparatus for an integrated energy system according to embodiments of the present disclosure will be described below with reference to the drawings. For problems that actual physical characteristics of the regional integrated energy system are disjointed from methods in the related art, so that space-time transfer mechanism of carbon emission in the regional integrated energy system cannot be clarified, and thus guidance on optimization decisions of the regional integrated energy system is limited, the present disclosure provides a carbon emission flow calculation method for a regional integrated energy system. In the method according to the present disclosure, standardization modeling of carbon emission of the regional integrated energy system can be obtained by establishing a steady-state carbon emission flow model of the regional integrated energy system based on a matrix expression of carbon emission flow, thereby obtaining an actual carbon emission flow of the regional integrated energy system. Therefore, it is possible to provide an accurate and effective method for analysis and measurement of the carbon emission of the regional integrated energy system, and basis for clarifying carbon emission responsibilities of different energy systems, measuring emission reduction contributions of different subjects, and discovering and identifying low-carbon weak links in the system. As a result, problems that the actual physical characteristics of the regional integrated energy system are disjointed from the methods in the related art, so that the space-time transfer mechanism of carbon emission in the regional integrated energy system cannot be clarified, and thus the guidance on the optimization decisions of the regional integrated energy system is limited and the like, can be solved.

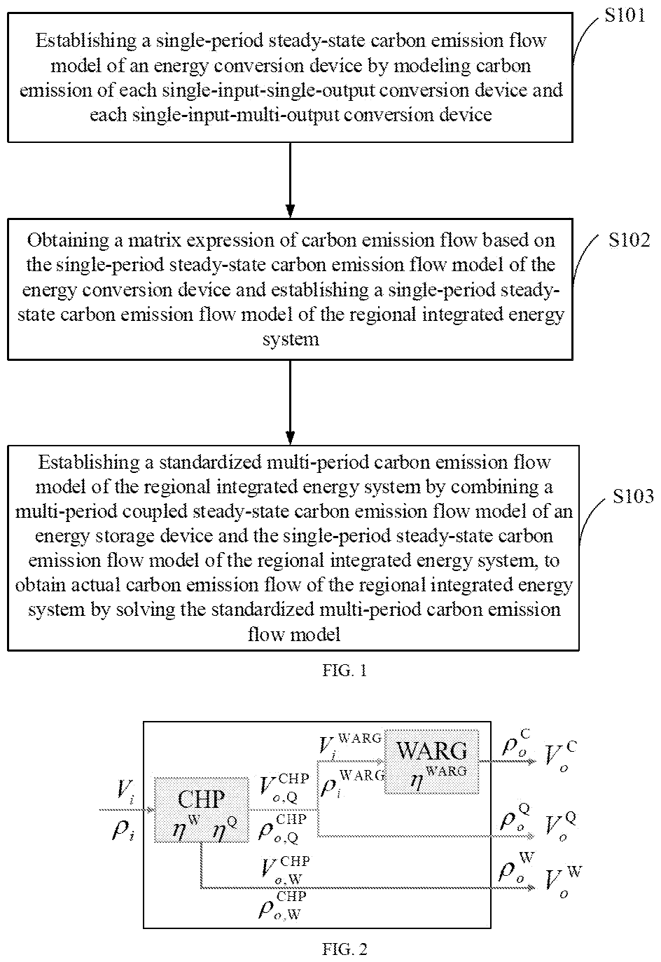

FIG. 1 is a flowchart of a carbon emission flow calculation method for a regional integrated energy system according to an embodiment of the present disclosure.

As shown in FIG. 1, the carbon emission flow calculation method for the regional integrated energy system includes actions at steps S101 to S103.

At step S101, a single-period steady-state carbon emission flow model of an energy conversion device is established by modeling carbon emission of each single-input-single-output conversion device and each single-input-multi-output conversion device.

In some embodiments of the present disclosure, the energy conversion device in a multi-energy system, such as a combined heat and power (CHP), an electric boiler (EB), an auxiliary boiler (AB), a compressor electrical refrigeration group (CERG), a water absorption refrigeration group (WARG), etc. may be classified into a first category, i.e., the single-input-single-output device, and a second category, i.e., the single-input-multiple-output device based on the number of input ports and the number of output ports. Further, most of these devices belong to the first category, and a few devices. such as CHP, belong to the second category. According to the embodiment of the present disclosure, carbon emission of each of the two categories of energy conversion devices can be modeled, respectively, thereby realizing full coverage of the energy conversion devices in the multi-energy system, which in turn ensures accuracy of the result.

In one embodiment of the present disclosure. a first carbon flow density relationship between an input port and an output port of the single-input-single-output conversion device satisfies:

ρₒ^{I}=ρᵢ^{I}Vᵢ^{I}/Vₒ^{I}=ρᵢ^{I}/η^{I},

where ρᵢ^{I} represents a carbon flow density at the input port of the single-input-single-output conversion device, ρₒ^{I} represents a carbon flow density at the output port of the single-input-single-output conversion device, Vᵢ^{I} represents input energy flow, Vₒ^{I} represents output energy flow, and η^{I} represents an efficiency.

A second carbon flow density relationship between an input port and output ports of the single-input-multi-output conversion device satisfies:

$${ρ}_{o , W}^{CHP} = \frac{{ρ}_{i}^{CHP}}{{η}^{W} + {ϵη}^{Q}} ,$$

$${ρ}_{o , Q}^{CHP} = \frac{{ϵρ}_{i}^{CHP}}{{η}^{W} + {ϵη}^{Q}} ,$$

where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and e represents a ratio of exergy to energy of a working medium.

In the actual implementation process, when the energy conversion device in the multi-energy system is the single-input-single-output conversion device, there is no carbon emission injection except the input or carbon emission outflow except the output during the operation according to the embodiment of the present disclosure. According to the conservation of carbon emission, carbon emission corresponding to input energy is equal to carbon emission corresponding to output energy, i.e.,

ρᵢ^{I}Vᵢ^{I}=ρₒ^{I}Vₒ^{I},

where ρᵢ^{I} represents a carbon flow density at an input port of the energy conversion device I (I=EB, AB, CERG, WARG, etc.), ρₒ^{I} represents a carbon flow density at an output port of the energy conversion device I (I=EB, AB, CERG, WARG, etc.), Vᵢ^{I} represents input energy flow, and Vₒ^{I} represents output energy flow.

According to the embodiment of the present disclosure, a relationship between the output energy flow and the input energy flow of the device may be expressed by using efficiency η^{I},i.e.,

Vₒ^{I}=η^{I}Vᵢ^{I}.

Then, a relationship between the carbon flow density at the input port and the carbon flow density at the output port of the single-input-single-output energy conversion device is obtained as:

ρₒ^{I}=ρᵢ^{I}Vᵢ^{I}/Vₒ^{I}=ρᵢ^{I}/η^{I}.

When the energy conversion device in the multi-energy system is the single-input-multi-output conversion device, taking CHP as an example for analysis, according to the embodiment of the present disclosure, the electric energy conversion efficiency η^{W} and the heat energy conversion efficiency η^{Q} can be defined respectively. and thus each of an electricity output and a heat output of the CHP is calculated as follows:

V_{o,W}^{CHP}=η^{W}Vᵢ^{CHP},

V_{o,Q}^{CHP}=η^{Q}Vᵢ^{CHP},

where Vᵢ^{CHP} represents an enery value of input natural gas, V_{o,W}^{CHP} represents the electricity output of the CHP, and V_{o,Q}^{CHP} represents the heat output of the CHP.

For this device, according to the conservation of carbon emission, carbon emission at the input port is equal to total carbon emission at the output ports, thus,

ρᵢ^{CHP}Vᵢ^{CHP}=ρ_{o,W}^{CHP}V_{o,W}^{CHP}+ρ_{o,Q}^{CHP}V_{o,Q}^{CHP},

where ρᵢ^{CHP} represents a carbon flow density at the input port. ρ_{o,W}^{CHP} represents a carbon flow density at the electricity output port, and ρ_{o,Q}^{CHP} represents a carbon flow density at the heat output port.

According to the embodiments of the present disclosure, total input carbon emission can be distributed to a plurality of output ports by an exergy analysis method. An exergy coefficient is defined as a ratio of the exergy of working medium to the energy. An exergy coefficient of the electric energy is 1, and an exergy coefficient of the heat energy is related to a temperature of the working medium. and is denoted by ϵ. According to the exergy analysis method, the carbon emissions at different output ports should be directly proportional to the exergy at the output ports, thus

$$\frac{{ρ}_{o , W}^{CHP} {V}_{o , W}^{CHP}}{{ρ}_{o , Q}^{CHP} {V}_{o , Q}^{CHP}} = \frac{{V}_{o , W}^{CHP}}{{V}_{o , Q}^{CHP} ϵ} .$$

Combined with the above equations, a carbon flow density relationship between the input port and the output port of CHP can be obtained as

$${ρ}_{o , W}^{CHP} = \frac{{ρ}_{i}^{CHP}}{{η}^{W} + {ϵη}^{Q}} ,$$

$${ρ}_{o , Q}^{CHP} = \frac{{ϵρ}_{i}^{CHP}}{{η}^{W} + {ϵη}^{Q}} ,$$

At step S102, a matrix expression of the carbon emission flow is obtained based on the single-period steady-state carbon emission flow model of the energy conversion device, and a single-period steady-state carbon emission flow model of the regional integrated energy system is established.

As a possible implementation, according to the embodiment of the present disclosure, the matrix expression of the carbon emission flow can be obtained based on the single-period steady-state carbon emission flow model of the energy conversion device, and then the single-period steady-state carbon emission flow model of the regional integrated energy system can be established. In the embodiments of the present disclosure, by establishing the single-period steady-state carbon emission flow model of the regional integrated energy system, it is possible to provide a basis for establishment of multi-period steady-state carbon emission flow model of the regional integrated energy system, so that calculation results of the carbon emission flow are more accurate, which is conducive to solving the coupling problem of carbon emission in energy dimension and time dimension in the regional integrated energy system.

In one embodiment of the present disclosure, the obtaining the matrix expression of the carbon emission flow based on the single-period steady-state carbon emission flow model of the energy conversion device, and establishing the single-period steady-state carbon emission flow model of the regional integrated energy system includes: determining a first carbon emission coupling matrix of the regional integrated energy system based on the first carbon flow density relationship, and determining a second carbon emission coupling matrix of the regional integrated energy system based on the second carbon flow density relationship; and calculating carbon flow rates at all output ports based on the first carbon emission coupling matrix and the second carbon emission coupling matrix.

For example, according to the embodiment of the present disclosure, the first carbon emission coupling matrix of the regional integrated energy system is determined based on the first carbon flow density relationship. the second carbon emission coupling matrix of the regional integrated energy system is determined based on the second carbon flow density relationship, and the carbon flow rates at all the output ports are calculated based on the first carbon emission coupling matrix and the second carbon emission coupling matrix. The calculation method of the carbon flow rates at all the output ports will be described in detail below. According to the embodiment of the present disclosure, the carbon flow rates at all the output ports can be calculated based on the carbon flow density of each of the single-input-single-output energy conversion device and the single-input-multiple-output energy conversion device. Therefore, the full coverage of the energy conversion devices in the multi-energy system can be realized, which can provide a basis for the subsequent establishment of the multi-period steady-state carbon emission flow model of the regional integrated energy system, so that the calculation results of the carbon emission flow is more accurate, which is conducive to solving the coupling problem of the carbon emission in the energy dimension and the time dimension in the regional integrated energy system.

In one embodiment of the present disclosure, the calculating the carbon flow rates at all the output ports based on the first carbon emission coupling matrix and the second carbon emission coupling matrix includes: obtaining carbon flow density vectors at the output ports based on the first carbon emission coupling matrix and the second carbon emission coupling matrix; and obtaining the carbon flow rates at all the output ports based on the carbon flow density vectors at the output ports. The carbon flow rates are each calculated based on the following equation:

Rₒ=ρₒ∘Vₒ,

where ρₒ represents the carbon flow density vectors at the output ports, Vₒ represents an output energy column vector, and ∘ represents a corresponding multiplication (Hadamard product) of two vector elements.

In some embodiments of the present disclosure, a coupling relationship of interconnection of different energy conversion devices in the regional integrated energy system can be defined and described by an input-output port model. A relationship between an input energy column vector Vᵢ and the output energy column vector Vₒ is characterized by a coupling matrix C, i.e.,

Vₒ=CVᵢ.

In the embodiment of the present disclosure, a carbon emission coupling matrix D of the regional integrated energy system can be defined for describing a relationship between a carbon flow density vector at the input port and an carbon flow density vector at the output port, and satisfies:

ρₒ=Dρᵢ,

where ρᵢ represents the carbon flow density vector at the input port, and ρₒ represents the carbon flow density vector at the output port.

Each element dᵢⱼ in the carbon emission coupling matrix D defines a relationship between a carbon flow density ρ_{o,i} at an i^{th} output port and a carbon flow density ρ_{i,j} at a j^{th} input port. Thus, ρₒ=Dρᵢ can also be expanded as:

$$[ \begin{matrix}{ρ}_{o , 1} \\ {ρ}_{o , 2} \\ ⋮ \\ {ρ}_{o , n}\end{matrix} ] = [ \begin{matrix}{d}_{11} & {d}_{12} & … & {d}_{1 m} \\ {d}_{21} & {d}_{22} & … & {d}_{2 m} \\ ⋮ & ⋮ & ⋱ & ⋮ \\ {d}_{n 1} & {d}_{n 2} & … & {d}_{nm}\end{matrix} ] [ \begin{matrix}{ρ}_{i , 1} \\ {ρ}_{i , 2} \\ ⋮ \\ {ρ}_{i , m}\end{matrix} ] .$$

Based on the energy flow of the energy hub, the carbon emission coupling matrix D can be obtained by using the above model, and then the carbon flow density vector at the output port can be obtained. Finally, the carbon flow rates at all the output ports can be calculated as:

Rₒ=ρₒ∘Vₒ,

where ∘ represents a corresponding multiplication (Hadamard product) of two vector elements.

The solution process of the carbon emission coupling matrix D is described below. Taking a simple energy hub shown in FIG. 2 as an example, the simple energy hub has one input port and three output ports, and energy flow of different forms are distinguished by arrows of different colors. In the embodiment of the present disclosure, when calculating the carbon flow rates at all the output ports, the carbon flow density vector at the input port and the carbon flow density vector at the output port satisfy:

$${ρ}_{i} = [ {ρ}_{i} ] ,$$

$${ρ}_{o} = {[ {ρ}_{o}^{W} , {ρ}_{o}^{Q} , {ρ}_{o}^{C} ]}^{T} ,$$

where ρᵢ represents the carbon flow density at the input port, ρₒ^{W} represents the carbon flow density at the electricity output port, ρₒ^{Q} represents the carbon flow density at the heat output port, and ρₒ^{C} represents the carbon flow density at a cooling energy output port.

According to the carbon emission flow model of CHP and WARG established at step S101, the following relationship can be obtained:

ρₒ^{C}=ρᵢ^{WARG}/η^{WARG},

ρₒ^{Q}=ρᵢ^{WARG}=ρ_{o,Q}^{CHP},

$${ρ}_{o}^{W} = {ρ}_{o , W}^{CHP} = \frac{{ρ}_{i}}{{η}^{W} + {ϵη}^{Q}} ,$$

$${ρ}_{o , Q}^{CHP} = \frac{{ϵρ}_{i}}{{η}^{W} + {ϵη}^{Q}} .$$

Based on the above equations, the carbon flow density vector relationship between the input port and the output ports can be obtained as follows:

$${ρ}_{o} = {[ \frac{1}{{η}^{w} + {εη}^{Q}} , \frac{ε}{{η}^{w} + {εη}^{Q}} , \frac{ε}{{η}^{WARG} ( {η}^{w} + {εη}^{Q} )} ]}^{T} {p}_{i} .$$

The carbon flow density at the input port is a model parameter, and the carbon flow density at each output port can be obtained based on the above equation, and then a carbon flow rate at each output port can be calculated by combining Rₒ=ρₒ∘Vₒ.

At step S103, a standardized multi-period carbon emission flow model of the regional integrated energy system is established by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

In the actual implementation process, according to the embodiment of the present disclosure, the standardized multi-period carbon emission flow model of the energy storage device in the regional integrated energy system is established by combining the single-period steady-state carbon emission flow model of the regional integrated energy system and the multi-period coupled steady-state carbon emission flow model of the energy storage device that are obtained in the above steps, to obtain the multi-period carbon emission flow model of the regional integrated energy system, thereby obtaining the actual carbon emission flow of the regional integrated energy system. According to the present disclosure, the standardization modeling of the carbon emission of the regional integrated energy system can be obtained by establishing the steady-state carbon emission flow model of the regional integrated energy system based on the matrix expression of the carbon emission flow, thereby obtaining the actual carbon emission flow of the regional integrated energy system. Therefore, it is possible to provide an accurate and effective method for carbon emission analysis and measurement of the regional integrated energy system and a basis for clarifying carbon emission responsibilities of different energy systems, measuring the emission reduction contributions of different subjects, and discovering and identifying low-carbon weak links in the system.

In one embodiment of the present disclosure, the establishing the standardized multi-period carbon emission flow model of the regional integrated energy system by combining the multi-period coupled steady-state carbon emission flow model of the energy storage device and the single-period steady-state carbon emission flow model of the regional integrated energy system includes: determining internal stored energy based on a current operating state of the energy storage device, and obtaining corresponding carbon emission, to determine a stored carbon flow rate; and establishing a period coupling relationship of the stored carbon flow rate based on the stored carbon flow rate, and determining a carbon flow density at an energy storage input port and a carbon flow density at an energy storage output port in any period, to generate the standardized multi-period carbon emission flow model.

According to the embodiments of the present disclosure, various types of energy storage devices may be abstracted as the single-input-single-output model, in which the input port represents energy absorption (energy charging), and the output port represents energy release (energy discharging). In an energy charging state, input energy is mixed with energy stored in the energy storage device, and carbon emission corresponding to the input energy and carbon emission corresponding to the energy stored in the energy storage device are also mixed with each other. In an energy discharging state, the energy stored in the energy storage device is output together with its corresponding carbon emission.

According to the embodiment of the present disclosure, assuming that input/output energy flow of the energy storage device at time period t is represented by Vₜ, where Vₜ>0 represents that the energy storage device operates in the energy charging state, and Vₜ<0 represents that the energy storage device operates in the energy discharging state. Thus, change in the stored energy in the energy storage device satisfies:

ΔE_{s,t}=ηₛVₜ,

where ηₛ represents a comprehensive efficiency of the energy storage device, and satisfies:

$${η}_{s} = \{ \begin{matrix}{η}^{C} , {V}_{t} > 0 \\ 1 / {η}^{D} , {V}_{t} \leq 0\end{matrix} ,$$

where η^{C} represents an energy charging efficiency of the energy storage device, and η^{D} represents an energy discharging efficiency of the energy storage device.

According to the embodiment of the present disclosure, carbon emission corresponding to the stored energy in the energy storage device can be defined as a stored carbon flow rate R_{s,t}^{ES}, and a period coupling relationship of the stored carbon flow rate satisfies:

R_{s,t}^{ES}=R_{s,t-1}^{ES}+ΔR_{s,t}^{ES},

where ΔR_{s,t}^{ES} represents change of the stored carbon flow rate R_{s,t}^{ES} at the period t, is related to an energy charging-and-discharging power and its corresponding carbon flow density, and satisfies:

$$Δ {R}_{s , t}^{ES} = \{ \begin{matrix}{ρ}_{i , t}^{ES} {V}_{t} , & {V}_{t} > 0 \\ {ρ}_{o , t}^{ES} {V}_{t} / {η}^{D} , & {V}_{t} \leq 0\end{matrix} ,$$

where ρ_{i,t}^{ES} represents a carbon flow density at the energy storage input port at the period t, and ρ_{o,t}^{ES} represents a carbon flow density at the energy storage output port at the period t.

The carbon flow density corresponding to the energy stored in the energy storage device is equal to a ratio of a coupled carbon emission to an energy value of this energy, and satisfies:

$${ρ}_{s , t}^{ES} = \frac{{R}_{s , t}^{ES}}{{E}_{s , t}^{ES}} = \frac{{R}_{s , t - 1}^{ES} + Δ {R}_{s , t}^{ES}}{{E}_{s , t - 1}^{ES} + Δ {E}_{s , t}^{ES}} .$$

In some embodiments, when the energy storage device operates in the energy discharging state, in accordance with energy distribution criterion, the carbon flow density at the output port is equal to a carbon flow density corresponding to the stored energy in the previous period, that is,

ρ_{o,t}^{ES}=ρ_{s,t-1}^{ES}, Vₜ≤0.

When the energy storage operates in the energy charging state, the carbon flow density ρ_{i,t}^{ES} at the input port is determined by external injected energy flow, which is a parameter of the model.

In summary, according to the embodiments of the present disclosure, based on the carbon emission flow technology, the carbon emission analysis can be expanded from a pure energy production side to a whole link from the energy production to energy consumption. Further, CO₂ is combined with real-time energy flow, thereby describing the carbon emission of the regional integrated energy system more comprehensively, clearly, and accurately. Compared with the traditional carbon emission flow technology, the theory of the carbon emission flow in the regional integrated energy system can realize real-time calculation of the carbon emission flow in various heterogeneous energy conversion, distribution, storage, and others through attaching corresponding “carbon labels” to energy flow of different forms. Therefore, it is possible to better solve the coupling problem of the carbon emission in the regional integrated energy system in the energy dimension and the time dimension.

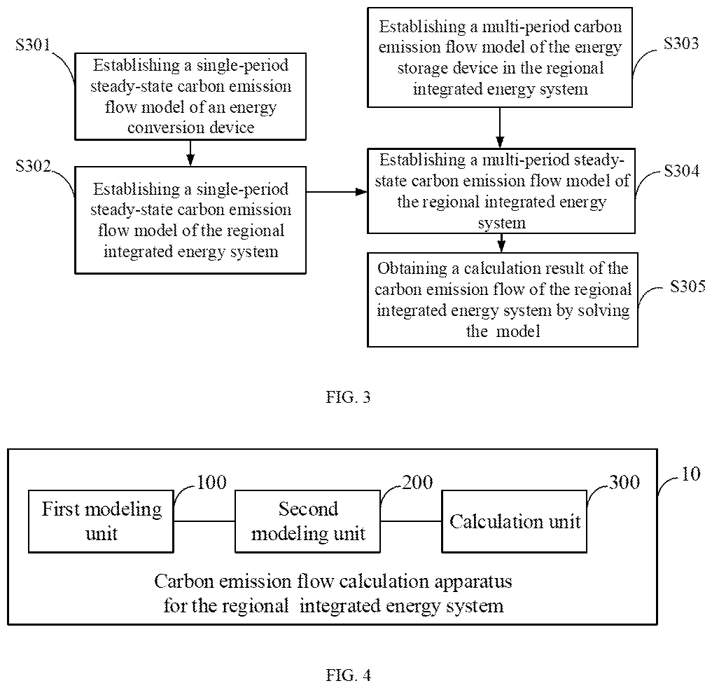

Embodiments of the present disclosure will be described in detail below with reference to FIG. 2 and FIG. 3.

As shown in FIG. 3, an embodiment of the present disclosure includes actions at steps S301 to S305.

At step S301: a single-period steady-state carbon emission flow model of an energy conversion device is established. In some embodiments of the present disclosure, energy conversion devices in a multi-energy system, such as a combined heat and power (CHP), an electric boiler (EB), an auxiliary boiler (AB), a compressor electrical refrigeration group (CERG), a water absorption refrigeration group (WARG), etc. may be classified into a first category, i.e., a single-input-single-output device, and a second category, i.e., a single-input-multiple-output device, based on the number of input ports and the number of output ports. Further, most of these devices belong to the first category, and a few devices, such as CHP, belong to the second category. According to the embodiment of the present disclosure, carbon emission of each of the two categories of energy conversion devices can be modeled, respectively, thereby realizing full coverage of the energy conversion devices in the multi-energy system, which in turn ensures accuracy of the result.

According to the embodiments of the present disclosure, when the energy conversion device in the multi-energy system is the single-input-single-output conversion device, there is no carbon emission injection except an input or carbon emission outflow except an output during the operation. According to conservation of carbon emission, carbon emission corresponding to input energy is equal to carbon emission corresponding to output energy:

ρᵢ^{I}Vᵢ^{I}=ρₒ^{I}Vₒ^{I},

where ρᵢ^{I} represents a carbon flow density at an input port of the energy conversion device I (I=EB, AB, CERG, WARG, etc.), ρₒ^{I} represents a carbon flow density at an output port of the energy conversion device I (I=EB, AB, CERG, WARG, etc.). Vᵢ^{I} represents input energy flow, and Vₒ^{I} represents output energy flow.

A relationship between the output energy flow and the input energy flow of the energy conversion device may be expressed by using an efficiency η^{I}, i.e.,

Vₒ^{I}=η^{I}Vᵢ^{I}.

Then, a relationship between the carbon flow density at the input port and the carbon flow density at the output port of the single-input-single-output energy conversion device is obtained as:

ρₒ^{I}=ρᵢ^{I}Vᵢ^{I}/Vₒ^{I}=ρᵢ^{I}/η^{I}.

When the energy conversion device in the multi-energy system is the single-input-multi-output conversion device, taking CHP as an example for analysis, according to the embodiment of the present disclosure, an electric energy conversion efficiency η^{W} and a heat energy conversion efficiency η^{Q} can be defined, respectively, and thus each of an electricity output and a heat output of the CHP is calculated as follows:

V_{o,W}^{CHP}=η^{W}Vᵢ^{CHP},

V_{o,Q}^{CHP}=η^{Q}Vᵢ^{CHP},

where Vᵢ^{CHP} represents an energy value of an input natural gas. V_{o,W}^{CHP} represents the electricity output of the CHP, and V_{o,Q}^{CHP} represents the heat output of the CHP.

For this kind of device, according to the conservation of carbon emission, carbon emission at the input port is equal to total carbon emission at the output ports, thus,

ρᵢ^{CHP}Vᵢ^{CHP}=ρ_{o,W}^{CHP}V_{o,W}^{CHP}+ρ_{o,Q}^{CHP}V_{o,Q}^{CHP}

ρᵢ^{CHP} represents a carbon flow density at the input port. ρ_{o,W}^{CHP} represents a carbon flow density at the electricity output port, and ρ_{o,Q}^{CHP} represents a carbon flow density at the heat output port.

According to the embodiments of the present disclosure, total input carbon emission can be distributed to a plurality of output ports by an exergy analysis method. An exergy coefficient is defined as a ratio of the exergy of working medium to the energy. An exergy coefficient of the electric energy is 1, and an exergy coefficient of the heat energy is related to a temperature of the working medium, and is denoted as ϵ. According to the exergy analysis method, the carbon emissions at different output ports should be directly proportional to the exergy at the output ports, thus

$$\frac{{ρ}_{o , W}^{CHP} {V}_{o , W}^{CHP}}{{ρ}_{o , Q}^{CHP} {V}_{o , Q}^{CHP}} = \frac{{V}_{o , W}^{CHP}}{{V}_{o , Q}^{CHP} ϵ} .$$

Combined with the above equation, the carbon flow density relationship between the input port and the output port of CHP can be obtained as

$${ρ}_{o , W}^{CHP} = \frac{{ρ}_{i}^{CHP}}{{η}^{W} + {ϵη}^{Q}} ,$$

$${ρ}_{o , Q}^{CHP} = \frac{{ϵρ}_{i}^{CHP}}{{η}^{W} + {ϵη}^{Q}} .$$

At step S302, a single-period steady-state carbon emission flow model of the regional integrated energy system is established. In the embodiment of the present disclosure, a coupling relationship of interconnection of different energy conversion devices in the regional integrated energy system can be defined and described by an input-output port model. A relationship between an input energy column vector Vᵢ and an output energy column vector Vₒ is characterized by a coupling matrix C, i.e.,

Vₒ=CVᵢ.

A carbon emission coupling matrix D of the regional integrated energy system can be defined for describing a relationship between an input port carbon flow density vector and an output port carbon flow density vector, and satisfies:

ρₒ=Dρᵢ,

where ρᵢ represents a carbon flow density vector at the input port, and ρₒ represents a carbon flow density vector at the output port.

Each element dᵢⱼ in the carbon emission coupling matrix D defines a relationship between a carbon flow density ρ_{o,i} at an i^{th} output port and a carbon flow density ρ_{i,j} at a j^{th} input port. Thus, ρₒ=Dρᵢ can also be expanded as:

$$[ \begin{matrix}{ρ}_{o , 1} \\ {ρ}_{o , 2} \\ ⋮ \\ {ρ}_{o , n}\end{matrix} ] = [ \begin{matrix}{d}_{11} & {d}_{12} & ⋯ & {d}_{1 m} \\ {d}_{21} & {d}_{22} & ⋯ & {d}_{2 m} \\ ⋮ & ⋮ & ⋱ & ⋮ \\ {d}_{n 1} & {d}_{n 2} & ⋯ & {d}_{nm}\end{matrix} ] [ \begin{matrix}{ρ}_{i , 1} \\ {ρ}_{i , 2} \\ ⋮ \\ {ρ}_{i , m}\end{matrix} ] .$$

Based on energy flow of an energy hub, the carbon emission coupling matrix D can be obtained by using the above model, and then the carbon flow density vector at the output port can be obtained. Finally, the carbon flow rates at all the output ports can be calculated as

Rₒ=ρₒ∘Vₒ,

where ∘ represents a corresponding multiplication (Hadamard product) of two vector elements.

The solution process of the carbon emission coupling matrix D is described below. Taking a simple energy hub shown in FIG. 2 as an example, the simple energy hub has one input port and three output ports, and energy flow of different forms are distinguished by arrows of different colors. In the embodiment of the present disclosure, when calculating the carbon flow rates at all the output ports, the carbon flow density vector at the input port and the carbon flow density vector at the output port are:

ρᵢ=[ρᵢ],

ρₒ=[ρₒ^{W}, ρₒ^{Q}, ρₒ^{C}]^{T},

where ρᵢ represents the carbon flow density at the input port, ρₒ^{W} represents the carbon flow density at the electricity output port, ρₒ^{Q} represents the carbon flow density at the heat output port, and ρₒ^{C} represents the carbon flow density at a cooling energy output port.

According to the carbon emission flow model of CHP and WARG established at step S101, the following relationship can be obtained:

ρₒ^{C}=ρᵢ^{WARG}/η^{WARG},

ρₒ^{Q}=ρᵢ^{WARG}=ρ_{o,Q}^{CHP},

$${ρ}_{o}^{W} = {ρ}_{o , W}^{CHP} = \frac{{ρ}_{i}}{{η}^{W} + {ϵη}^{Q}} ,$$

$${ρ}_{o , Q}^{CHP} = \frac{{ϵρ}_{i}}{{η}^{W} + {ϵη}^{Q}} .$$

Based on the above equations, the carbon flow density vector relationship between the input port and the output ports can be obtained as follows:

$${ρ}_{o} = {[ \frac{1}{{η}^{w} + {εη}^{Q}} , \frac{ε}{{η}^{w} + {εη}^{Q}} , \frac{ϵ}{{η}^{WARG} ( {η}^{w} + {εη}^{Q} )} ]}^{T} {ρ}_{i} .$$

The carbon flow density at the input port is the model parameter, and the carbon flow density at each output port can be obtained based on the above equation. and then a carbon flow rate at each output port can be calculated by combining Rₒ=ρₒ∘Vₒ.

At step S303, a multi-period carbon emission flow model of the energy storage device in the regional integrated energy system is established. According to the embodiment of the present disclosure, various types of energy storage devices may be abstracted as the single-input-single-output model, in which the input port represents energy absorption (energy charging), and the output port represents energy release (energy discharging). In an energy charging state, input energy is mixed with energy stored in the energy storage device, and carbon emission corresponding to the input energy and carbon emission corresponding to the energy stored in the energy storage device are also mixed with each other. In an energy discharging state, the energy stored in the energy storage device is output together with its corresponding carbon emission.

According to the embodiment of the present disclosure, assuming that input/output energy flow of the energy storage device at time period t is represented by Vₜ, where Vₜ>0 represents that the energy storage device operates in the energy charging state, and Vₜ<0 represents that the energy storage device operates in the energy discharging state. Thus, change in the stored energy in the energy storage device satisfies:

ΔE_{s,t}=ηₛVₜ,

where ηₛ represents a comprehensive efficiency of the energy storage device, and satisfies:

$${η}_{s} = \{ \begin{matrix}{η}^{C} , & {V}_{t} > 0 \\ 1 / {η}^{D} , & {V}_{t} \leq 0\end{matrix} ,$$

where η^{C} represents an energy charging efficiency of the energy storage device, and η^{D} represents an energy discharging efficiency of the energy storage device.

According to the embodiment of the present disclosure, carbon emission corresponding to the stored energy in the energy storage device can be defined as a stored carbon flow rate R_{s,i}^{ES}, and a period coupling relationship of the stored carbon flow rate satisfies:

R_{s,t}^{ES}=R_{s,t-1}^{ES}+ΔR_{s,t}^{ES},

where ΔR_{s,t}^{ES} represents change of the stored carbon flow rate R_{s,t}^{ES} at the period t, is related to an energy charging-and-discharging power and its corresponding carbon flow density, and satisfies:

$$Δ {R}_{s , t}^{ES} = \{ \begin{matrix}{ρ}_{i , t}^{ES} {V}_{t} , & {V}_{t} > 0 \\ {ρ}_{o , t}^{ES} {V}_{t} / {η}^{D} , & {V}_{t} \leq 0\end{matrix} ,$$

where ρ_{i,t}^{ES} represents a carbon flow density at the energy storage input port at the period t. and ρ_{o,t}^{ES} represents a carbon flow density at the energy storage output port at the period t.

The carbon flow density corresponding to the energy stored in the energy storage device is equal to a ratio of a coupled carbon emission to an energy value of this energy, that is:

$${ρ}_{s , t}^{ES} = \frac{{R}_{s , t}^{ES}}{{E}_{s , t}^{ES}} = \frac{{R}_{s , t - 1}^{ES} + Δ {R}_{s , t}^{ES}}{{E}_{s , t - 1}^{ES} + Δ {E}_{s , t}^{ES}} .$$

In some embodiments, when the energy storage device operates in the energy discharging state, in accordance with energy distribution criterion, the carbon flow density at the output port is equal to a carbon flow density corresponding to the stored energy in the previous period, that is,

ρ_{o,t}^{ES}=ρ_{s,t-1}^{ES}, Vₜ≤0.

When the energy storage operates in the energy charging state, the carbon flow density ρ_{i,t}^{ES} at the input port is determined by external injected energy flow, which is a parameter of the model.

At step S304, a multi-period steady-state carbon emission flow model of the regional integrated energy system is established. At step S303, according to the embodiment, the multi-period carbon emission flow model of the energy storage device is established. Since only the energy storage device has the period coupling relationship of the energy in the energy conversion and storage links, the multi-period carbon emission flow model of the regional integrated energy system can be obtained by combining the matrix single-period steady-state carbon emission flow model established at the steps S301 and S302.

At step S305, a calculation result of the carbon emission flow of the regional integrated energy system is obtained by solving the model.

Embodiments of the present disclosure provide a carbon emission flow calculation method for a regional integrated energy system. In the method, the standardization modeling of the carbon emission of the regional integrated energy system can be obtained by establishing the steady-state carbon emission flow model of the regional integrated energy system based on the matrix expression of carbon emission flow, thereby obtaining the actual carbon emission flow of the regional integrated energy system. Therefore, it is possible to provide an accurate and effective method for analysis and measurement of the carbon emission of the regional integrated energy system, and basis for clarifying carbon emission responsibilities of different energy systems, measuring emission reduction contributions of different subjects, and discovering and identifying low-carbon weak links in the system. As a result, problems that the actual physical characteristics of the regional integrated energy system are disjointed from the methods in the related art, so that the space-time transfer mechanism of carbon emission in the regional integrated energy system cannot be clarified, and thus the guidance on the optimization decisions of the regional integrated energy system is limited and the like, can be solved.

A carbon emission flow calculation apparatus for a regional integrated energy system according to an embodiment of the present disclosure will be described below with reference to the accompanying drawings.

FIG. 4 is a schematic structural diagram of a carbon emission flow calculation apparatus for a regional integrated energy system according to an embodiment of the present disclosure.

As shown in FIG. 4, the carbon emission flow calculation apparatus 10 for the regional integrated energy system includes a first modeling unit 100, a second modeling unit 200, and a calculation unit 300.

In some embodiments of the present disclosure, the first modeling unit 100 is configured to establish a single-period steady-state carbon emission flow model of an energy conversion device by modeling carbon emission of each single-input-single-output conversion device and each single-input-multi-output conversion device.

The second modeling unit 200 is configured to establish a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

In one embodiment of the present disclosure, a first carbon flow density relationship between an input port and an output port of the single-input-single-output conversion device satisfies:

ρₒ^{I}=ρᵢ^{I}Vᵢ^{I}/Vₒ^{I}=ρᵢ^{I}/η^{I},

where ρᵢ^{I} represents a carbon flow density at the input port of the single-input-single-output conversion device, ρₒ^{I} represents a carbon flow density at the output port of the single-input-single-output conversion device. Vᵢ^{I} represents input energy flow, Vₒ^{I} represents output energy flow, and η^{I} represents an efficiency.

A second carbon flow density relationship between an input port and output ports of the single-input-multi-output conversion device satisfies:

$${ρ}_{o , W}^{CHP} = \frac{{ρ}_{i}^{CHP}}{{η}^{W} + {ϵη}^{Q}} ,$$

$${ρ}_{o , Q}^{CHP} = \frac{{ϵρ}_{i}^{CHP}}{{η}^{W} + {ϵη}^{Q}} ,$$

where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and ϵ represents a ratio of exergy to energy of a working medium.

In one embodiment of the present disclosure, the second modeling unit 200 includes a conversion sub-unit and a calculation sub-unit.

The conversion sub-unit is configured to determine a first carbon emission coupling matrix of the regional integrated energy system based on the first carbon flow density relationship, and determine a second carbon emission coupling matrix of the regional integrated energy system based on the second carbon flow density relationship.

The calculation sub-unit is configured to obtain carbon flow density vectors at the output ports based on the first carbon emission coupling matrix and the second carbon emission coupling matrix, and to obtain the carbon flow rates at all the output ports based on the carbon flow density vectors at the output ports. The carbon flow rates are each calculated based on the following equation:

Rₒ=ρₒ∘Vₒ,

where ρₒ represents the carbon flow density vector at each of the output ports, Vₒ represents an output energy column vector, and ∘ represents a corresponding multiplication (Hadamard product) of two vector elements.

In one embodiment of the present disclosure, the calculation unit 300 is further configured to: determine internal stored energy based on a current operating state of the energy storage device, and obtain corresponding carbon emission, to determine a stored carbon flow rate, and to establish a period coupling relationship of the stored carbon flow rate based on the stored carbon flow rate and determine a carbon flow density at an energy storage input port and a carbon flow density at an energy storage output port in any period, to generate the standardized multi-period carbon emission flow model.

It should be noted that, the foregoing explanation of the embodiments of the carbon emission flow calculation method for the regional integrated energy system is also applicable to the embodiments of the carbon emission flow calculation apparatus for the regional integrated energy system, and thus the description thereof in detail will be omitted herein.

With the carbon emission flow calculation apparatus for the regional integrated energy system according to the embodiment of the present disclosure, the standardization modeling of the carbon emission of the regional integrated energy system can be obtained by establishing the steady-state carbon emission flow model of the regional integrated energy system based on the matrix expression of carbon emission flow, thereby obtaining the actual carbon emission flow of the regional integrated energy system. Therefore, it is possible to provide an accurate and effective method for analysis and measurement of the carbon emission of the regional integrated energy system, and basis for clarifying carbon emission responsibilities of different energy systems, measuring emission reduction contributions of different subjects, and discovering and identifying low-carbon weak links in the system. As a result, problems that the actual physical characteristics of the regional integrated energy system are disjointed from the method in the related art, so that the space-time transfer mechanism of carbon emission in the regional integrated energy system cannot be clarified, and thus the guidance on the optimization decisions of the regional integrated energy system is limited and the like, can be solved.

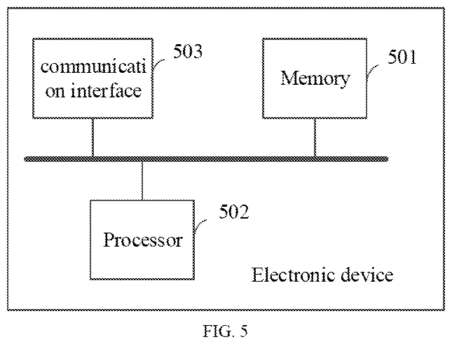

FIG. 5 is a schematic structural diagram of an electronic device according to an embodiment of the present disclosure. The electronic device may include a memory 501, a processor 502, and a computer program stored in the memory 501 and executable on the processor 502. The processor is configured to execute the computer program to implement the carbon emission flow calculation method for the regional integrated energy system as described above.

Further, the electronic device further includes a communication interface 503 configured for communication between the memory 501 and the processor 502.

The memory 501 is configured to store the computer program executable on the processor 502.

The memory 501 may include high-speed RAM memory and may also include non-volatile memory such as at least one disk memory.

If the memory 501, the processor 502 and the communication interface 503 are implemented separately, the communication interface 503, the memory 501. and the processor 502 may be connected and communicate with each other through a bus. The bus can be an Industry Standard Architecture (ISA) bus, a Peripheral Component (PCI) bus, or an Extended Industry Standard Architecture (EISA) bus. The bus can be divided into an address bus, a data bus, a control bus, and the like. For ease of presentation, the bus is denoted only by one thick line in FIG. 5, which, however, not mean that there is only one bus or one type of bus.

In some embodiments, if the memory 501, the processor 502, and the communication interface 503 are implemented by being integrated on a single chip, the memory 501, the processor 502, and the communication interface 503 can communicate with each other via an internal interface.

The processor 502 may be a Central Processing Unit (CPU), an Application Specific Integrated Circuit (ASIC), or one or more integrated circuits configured to implement embodiments of the present disclosure.

Embodiments of the present disclosure also provide a computer-readable storage medium, having a computer program stored thereon. The computer program, when executed by a processor, implements the carbon emission flow calculation method for the regional integrated energy system as described above.

In the description of this specification, descriptions with reference to the terms “an embodiment”, “some embodiments”, “illustrative embodiments”, “an example”, “a specific example”, “some examples”, etc., mean that specific features, structure, materials, or characteristics described in conjunction with the embodiment or example are included in at least one embodiment or example of the present disclosure. In this specification, the schematic representations of the above terms do not necessarily refer to the same embodiment or example. Moreover, the described specific features, structures, materials or characteristics may be combined in any one or more embodiments or examples in a suitable manner. In addition, different embodiments or examples and features of different embodiments or examples described in the specification may be combined by those skilled in the art without mutual contradiction.

In addition, terms such as “first” and “second” are used herein for purposes of description and are not intended to indicate or imply relative importance or significance. Thus, the feature associated with “first” and “second” may include one or more this feature. In the description of the present disclosure, “a plurality of” means at least two, for example, two or three, unless specified otherwise.

Any process or method described in a flow chart or otherwise described herein may be understood to include one or more modules, segments or portions of codes of executable instructions for achieving specific logical functions or steps in the process, and the scope of preferred embodiments of the present disclosure includes other implementations, in which functions may be implemented in an order other than the shown or discussed order, including in a substantially identical order or in an opposite order, which should be understood by those skilled in the art.

The logic and/or step described in other manners herein or shown in the flow chart, for example, a particular sequence table of executable instructions for realizing the logical function, may be specifically achieved in any computer readable medium to be used by the instruction execution system, device, or equipment (such as the system based on computers, the system including processors or other systems capable of obtaining the instruction from the instruction execution system, device, and equipment and executing the instruction), or to be used in combination with the instruction execution system, device, and equipment. As to the specification, “the computer readable medium” may be any device adaptive for including, storing, communicating, propagating or transferring programs to be used by or in combination with the instruction execution system, device, or equipment. More specific examples of the computer readable medium include but are not limited to: an electronic connection (an electronic device) with one or more wires, a portable computer enclosure (a magnetic device), a random access memory (RAM), a read only memory (ROM), an erasable programmable read-only memory (EPROM or a flash memory), an optical fiber device, and a portable compact disk read-only memory (CDROM). In addition, the computer readable medium may even be a paper or other appropriate medium capable of printing programs thereon, this is because, for example, the paper or other appropriate medium may be optically scanned and then edited, decrypted or processed with other appropriate methods when necessary to obtain the programs in an electric manner, and then the programs may be stored in the computer memories.

It should be understood that each part of the present disclosure may be realized by hardware, software, firmware or combination thereof. In the above embodiments, N steps or methods may be realized by software or firmware stored in the memory and executed by an appropriate instruction execution system. For example, if it is realized by the hardware, likewise in another embodiment, it may be realized by one or a combination of the following techniques known in the art: a discrete logic circuit having a logic gate circuit for realizing a logic function of a data signal, an application-specific integrated circuit having an appropriate combination logic gate circuit, a programmable gate array (PGA), a field programmable gate array (FPGA), etc.

It should be understood by those skilled in the art that all or a part of the steps carried by the method in the above-described embodiments may be completed by relevant hardware instructed by a program. The program may be stored in a computer readable storage medium. The program, when executed, includes one or a combination of the steps of the method embodiments of the present disclosure.

In addition, individual functional units of the embodiments of the present disclosure may be integrated into a processing module, or may be separate physical existence, or two or more units may be integrated in one module. The integrated module as described above may be implemented in the form of hardware, or may be implemented in the form of a software functional module. If the integrated module is implemented in the form of a software functional module and sold or used as a separate product, the integrated module may also be stored in a computer readable storage medium.

The storage medium mentioned above may be read-only memories, magnetic disks or CD, etc. Although embodiments of the present disclosure have been shown and described above, it would be appreciated that the above embodiments are explanatory and cannot be construed to limit the present disclosure. In addition, changes, modification, alternatives, and variations can be made to the above embodiments by those of ordinary skill in the art without departing from scope of the present disclosure.

What is claimed is:

1. A carbon emission flow calculation method for a regional integrated energy system, the method comprising:
establishing a single-period steady-state carbon emission flow model of an energy conversion device by modeling carbon emission of each single-input-single-output conversion device and each single-input-multi-output conversion device;
obtaining a matrix expression of carbon emission flow based on the single-period steady-state carbon emission flow model of the energy conversion device and establishing a single-period steady-state carbon emission flow model of the regional integrated energy system; and
establishing a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

2. The method according to claim 1, wherein:
a first carbon flow density relationship between an input port and an output port of the single-input-single-output conversion device satisfies:
ρₒ^{I}=ρᵢ^{I}Vᵢ^{I}/Vₒ^{I}=ρᵢ^{I}/η^{I},
where ρᵢ^{I} represents a carbon flow density at the input port of the single-input-single-output conversion device, ρₒ^{I} represents a carbon flow density at the output port of the single-input-single-output conversion device. Vᵢ^{I} represents input energy flow, Vₒ^{I} represents output energy flow, and η^{I} represents an efficiency; and
a second carbon flow density relationship between an input port and output ports of the single-input-multi-output conversion device satisfies:
$${ρ}_{o , W}^{CHP} = \frac{{ρ}_{i}^{CHP}}{{η}^{W} + {ϵη}^{Q}} ,$$
$${ρ}_{o , Q}^{CHP} = \frac{{ϵρ}_{i}^{CHP}}{{η}^{W} + {ϵη}^{Q}} ,$$
ρᵢ^{CHP} represents a carbon flow density at the input port. ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and ϵ represents a ratio of exergy to energy of a working medium.

3. The method according to claim 2, wherein said obtaining the matrix expression of the carbon emission flow based on the single-period steady-state carbon emission flow model of the energy conversion device and establishing the single-period steady-state carbon emission flow model of the regional integrated energy system comprises:
determining a first carbon emission coupling matrix and a second carbon emission coupling matrix of the regional integrated energy system based on the first carbon flow density relationship and the second carbon flow density relationship, respectively; and
calculating carbon flow rates at all output ports based on the first carbon emission coupling matrix and the second carbon emission coupling matrix.

4. The method according to claim 3, wherein said calculating the carbon flow rates at all the output ports based on the first carbon emission coupling matrix and the second carbon emission coupling matrix comprises:
obtaining carbon flow density vectors at the output ports based on the first carbon emission coupling matrix and the second carbon emission coupling matrix; and
obtaining the carbon flow rates at all the output ports based on the carbon flow density vectors at the output ports, wherein the carbon flow rates are each calculated based on the following equation:
Rₒ=ρₒ∘Vₒ,
where ρₒ represents the carbon flow density vector at each of the output ports, Vₒ represents an output energy column vector, and ∘ represents a corresponding multiplication (Hadamard product) of two vector elements.

5. The method according to claim 1, wherein said establishing the standardized multi-period carbon emission flow model of the regional integrated energy system by combining the multi-period coupled steady-state carbon emission flow model of the energy storage device and the single-period steady-state carbon emission flow model of the regional integrated energy system comprises:
determining internal stored energy based on a current operating state of the energy storage device, and obtaining corresponding carbon emission, to determine a stored carbon flow rate; and
establishing a period coupling relationship of the stored carbon flow rate based on the stored carbon flow rate, and determining a carbon flow density at an energy storage input port and a carbon flow density at an energy storage output port in any period, to generate the standardized multi-period carbon emission flow model.

6. A carbon emission flow calculation apparatus for a regional integrated energy system, the apparatus comprising:
a first modeling unit configured to establish a single-period steady-state carbon emission flow model of an energy conversion device by modeling carbon emission of each single-input-single-output conversion device and each single-input-multi-output conversion device;
a second modeling unit configured to obtain a matrix expression of carbon emission flow based on the single-period steady-state carbon emission flow model of the energy conversion device and to establish a single-period steady-state carbon emission flow model of the regional integrated energy system; and
a calculation unit configured to establish a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

7. The apparatus according to claim 6, wherein:
a first carbon flow density relationship between an input port and an output port of the single-input-single-output conversion device satisfies:
ρₒ^{I}=ρᵢ^{I}Vᵢ^{I}/Vₒ^{I}=ρᵢ^{I}/η^{I},
where ρᵢ^{I} represents a carbon flow density at the input port of the single-input-single-output conversion device, ρₒ^{I} represents a carbon flow density at the output port of the single-input-single-output conversion device, Vᵢ^{I} represents input energy flow, Vₒ^{I} represents output energy flow, and η^{I} represents an efficiency; and
a second carbon flow density relationship between an input port and output ports of the single-input-multi-output conversion device satisfies:
$${ρ}_{o , W}^{CHP} = \frac{{ρ}_{i}^{CHP}}{{η}^{W} + {ϵη}^{Q}} ,$$
$${ρ}_{o , Q}^{CHP} = \frac{{ϵρ}_{i}^{CHP}}{{η}^{W} + {ϵη}^{Q}} ,$$
where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and ϵ represents a ratio of exergy to energy of a working medium.

8. The apparatus according to claim 7, wherein the second modeling unit comprises:
a conversion sub-unit configured to determine a first carbon emission coupling matrix and a second carbon emission coupling matrix of the regional integrated energy system based on the first carbon flow density relationship and the second carbon flow density relationship, respectively; and
a calculation sub-unit configured to calculate carbon flow rates at all output ports based on the first carbon emission coupling matrix and the second carbon emission coupling matrix.

9. The apparatus according to claim 8, wherein the calculation sub-unit is further configured to:
obtain carbon flow density vectors at the output ports based on the first carbon emission coupling matrix and the second carbon emission coupling matrix; and
obtain the carbon flow rates at all the output ports based on the carbon flow density vectors at the output ports, wherein the carbon flow rates are each calculated based on the following equation:
Rₒ=ρₒ∘Vₒ,
where ρₒ represents the carbon flow density vector at each of the output ports, Vₒ represents an output energy column vector, and ∘ represents a corresponding multiplication (Hadamard product) of two vector elements.

10. The apparatus according to claim 6, wherein the calculation unit is further configured to:
determine internal stored energy based on a current operating state of the energy storage device, and obtain corresponding carbon emission, to determine a stored carbon flow rate; and
establish a period coupling relationship of the stored carbon flow rate based on the stored carbon flow rate, and determine a carbon flow density at an energy storage input port and a carbon flow density at an energy storage output port in any period, to generate the standardized multi-period carbon emission flow model.

11. An electronic device, comprising:
a memory;
a processor; and
a computer program stored in the memory and executable on the processor,
wherein the processor is configured to execute the computer program to cause the electronic device to:
establish a single-period steady-state carbon emission flow model of an energy conversion device by modeling carbon emission of each single-input-single-output conversion device and each single-input-multi-output conversion device:
obtain a matrix expression of carbon emission flow based on the single-period steady-state carbon emission flow model of the energy conversion device and establishing a single-period steady-state carbon emission flow model of the regional integrated energy system; and
establish a standardized multi-period carbon emission flow model of the regional integrated energy system by combining a multi-period coupled steady-state carbon emission flow model of energy storage devices and the single-period steady-state carbon emission flow model of the regional integrated energy system, to obtain actual carbon emission flow of the regional integrated energy system by solving the standardized multi-period carbon emission flow model.

12. The electronic device according to claim 11, wherein:
a first carbon flow density relationship between an input port and an output port of the single-input-single-output conversion device satisfies:
ρₒ^{I}=ρᵢ^{I}Vᵢ^{I}/Vₒ^{I}=ρᵢ^{I}/η^{I},
where ρᵢ^{I} represents a carbon flow density at the input port of the single-input-single-output conversion device, ρₒ^{I} represents a carbon flow density at the output port of the single-input-single-output conversion device. Vᵢ^{I} represents input energy flow. Vₒ^{I} represents output energy flow, and η^{I} represents an efficiency; and
a second carbon flow density relationship between an input port and output ports of the single-input-multi-output conversion device satisfies:
$${ρ}_{o , W}^{CHP} = \frac{{ρ}_{i}^{CHP}}{{η}^{W} + {ϵη}^{Q}} ,$$
$${ρ}_{o , Q}^{CHP} = \frac{{ϵρ}_{i}^{CHP}}{{η}^{W} + {ϵη}^{Q}} ,$$
where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and ϵ represents a ratio of exergy to energy of a working medium.

13. The electronic device according to claim 12, wherein the processor is further configured to execute the computer program to cause the electronic device to:
determine a first carbon emission coupling matrix and a second carbon emission coupling matrix of the regional integrated energy system based on the first carbon flow density relationship and the second carbon flow density relationship, respectively; and
calculate carbon flow rates at all output ports based on the first carbon emission coupling matrix and the second carbon emission coupling matrix.

14. The electronic device according to claim 13, wherein the processor is further configured to execute the computer program to cause the electronic device to:
obtain carbon flow density vectors at the output ports based on the first carbon emission coupling matrix and the second carbon emission coupling matrix; and
obtain the carbon flow rates at all the output ports based on the carbon flow density vectors at the output ports, wherein the carbon flow rates are each calculated based on the following equation:
Rₒ=ρₒ∘Vₒ,
where ρₒ represents the carbon flow density vector at each of the output ports, Vₒ represents an output energy column vector, and ∘ represents a corresponding multiplication (Hadamard product) of two vector elements.

15. The method according to claim 11, wherein the processor is further configured to execute the computer program to cause the electronic device to:
determine internal stored energy based on a current operating state of the energy storage device, and obtaining corresponding carbon emission, to determine a stored carbon flow rate; and
establish a period coupling relationship of the stored carbon flow rate based on the stored carbon flow rate, and determining a carbon flow density at an energy storage input port and a carbon flow density at an energy storage output port in any period, to generate the standardized multi-period carbon emission flow model.

16. A computer-readable storage medium, having a computer program stored thereon, wherein the computer program, when executed by a processor, implements the carbon emission flow calculation method for the regional integrated energy system according to claim 1.

17. The computer-readable storage medium according to claim 16, wherein:
a first carbon flow density relationship between an input port and an output port of the single-input-single-output conversion device satisfies:
ρₒ^{I}=ρᵢ^{I}Vᵢ^{I}/Vₒ^{I}=ρᵢ^{I}/η^{I},
where ρᵢ^{I} represents a carbon flow density at the input port of the single-input-single-output conversion device, ρₒ^{I} represents a carbon flow density at the output port of the single-input-single-output conversion device, Vᵢ^{I} represents input energy flow. Vₒ^{I} represents output energy flow, and η^{I} represents an efficiency; and
a second carbon flow density relationship between an input port and output ports of the single-input-multi-output conversion device satisfies:
$${ρ}_{o , W}^{CHP} = \frac{{ρ}_{i}^{CHP}}{{η}^{W} + {ϵη}^{Q}} ,$$
$${ρ}_{o , Q}^{CHP} = \frac{{ϵρ}_{i}^{CHP}}{{η}^{W} + {ϵη}^{Q}} ,$$
where ρᵢ^{CHP} represents a carbon flow density at the input port, ρ_{o,W}^{CHP} represents a carbon flow density at an electricity output port, and ρ_{o,Q}^{CHP} represents a carbon flow density at a heat output port, η^{W} represents an electric energy conversion efficiency, η^{Q} represents a heat energy conversion efficiency, and e represents a ratio of exergy to energy of a working medium.

18. The computer-readable storage medium according to claim 17, wherein said obtaining the matrix expression of the carbon emission flow based on the single-period steady-state carbon emission flow model of the energy conversion device and establishing the single-period steady-state carbon emission flow model of the regional integrated energy system comprises:
determining a first carbon emission coupling matrix and a second carbon emission coupling matrix of the regional integrated energy system based on the first carbon flow density relationship and the second carbon flow density relationship, respectively; and
calculating carbon flow rates at all output ports based on the first carbon emission coupling matrix and the second carbon emission coupling matrix.

19. The computer-readable storage medium according to claim 18, wherein said calculating the carbon flow rates at all the output ports based on the first carbon emission coupling matrix and the second carbon emission coupling matrix comprises:
obtaining carbon flow density vectors at the output ports based on the first carbon emission coupling matrix and the second carbon emission coupling matrix; and
obtaining the carbon flow rates at all the output ports based on the carbon flow density vectors at the output ports, wherein the carbon flow rates are each calculated based on the following equation:
Rₒ=ρₒ∘Vₒ,
where ρₒ represents the carbon flow density vector at each of the output ports, Vₒ represents an output energy column vector, and ∘ represents a corresponding multiplication (Hadamard product) of two vector elements.

20. The computer-readable storage medium according to claim 16, wherein said establishing the standardized multi-period carbon emission flow model of the regional integrated energy system by combining the multi-period coupled steady-state carbon emission flow model of the energy storage device and the single-period steady-state carbon emission flow model of the regional integrated energy system comprises:
determining internal stored energy based on a current operating state of the energy storage device, and obtaining corresponding carbon emission, to determine a stored carbon flow rate; and
establishing a period coupling relationship of the stored carbon flow rate based on the stored carbon flow rate, and determining a carbon flow density at an energy storage input port and a carbon flow density at an energy storage output port in any period, to generate the standardized multi-period carbon emission flow model.
